(19) United States
(12) Patent Application Publication
(10) Pub. No.: US 2006/0279286 A1
(43) Pub. Date: Dec. 14, 2006

(54) Safety-protective changeover switch of a high voltage tester

(75) Inventor: Mu-Chun Lin, Taichung (TW)

Correspondence Address: TOXELL LAW OFFICE PLLC;SUITE 1404, 5205 LEESBURG PIKE, FALLS CHURCH, VA, 22041, US

(73) Assignee: Chyng Hong Electronic Co.

(21) Appl. No.: 11/150,136

(22) Filed: Jun. 13, 2005

(51) Int. Cl. G01R 31/327

(52) U.S. Cl. 324/422

(57) ABSTRACT

A safety-protective changeover switch of a high voltage tester includes a start switch and a stop switch for controlling passage and cutting-off of high voltage. Both the switches have respectively two sets of connection points, which, through a reference voltage, pass a voltage signal to a control circuit, which then controls to cut off or to pass high voltage for protecting the safety of a user.

### BACKGROUND OF THE INVENTION

1. Field of the Invention

This invention relates to a safety-protective switch of a high voltage tester, especially one able to control precisely passage and shutdown of high voltage for protecting a user safely.

2. Description of the Prior Art

Usually, electric appliances, for sake of quality, must be tested with a series of quality control before being qualified for sale. Among them are at least the tests of high voltage tolerance, insulation and ground connection, etc. High voltage tolerance, especially, is the most important because it is to test leakage current value. If an appliance's leakage current value is beyond the standard one, it represents the possibility of current leakage out of the appliance. Therefore, to check the tolerance to high voltage is a very important stage to guaranty user's safety.

The procedure of high voltage test is to connect the high voltage tester to the outer shell of the appliance and power source respectively, then, turn on the switch of the high voltage tester to output high voltage for testing. The design of the conventional switch, as shown in FIGS. 1 and 2, is always composed of a single a-connection switch or a single b-connection switch. The a-connection switch is an open-circuit-status switch and the b-connection switch is a close-circuit-status switch. Following is the operation mechanism of the conventional switch. As shown in FIG. 1, when the button 101 of said a-connection switch 1 is pressed up, the movable connecting point 102 inside of it moves to contact with the fixed connecting point 103 and alter the original open-circuit-status into close-circuit-status. In reverse, as shown in FIG. 2, when the button 201 of said b-connection switch 2 is pressed, the movable connecting point 202 inside of it moves to contact with the fixed connecting point 203 and alter the original close-circuit-status into open-circuit-status. These are the known a-connection point or b-connection point switches use in the known voltage testers. But, coil springs 104 and 204 may become aged to lose their elasticity and the contact between the movable connecting points 102 and 202 or the fixed connecting points 103 and 203 may get failed during operation. Such an abnormality may cause an accident of voltage shock to a user. Therefore, a voltage tester with a safety switch is really very important.

### SUMMARY OF THE INVENTION

The prime object of this invention is to offer a safety-protective changeover switch of a high voltage tester.

The invention includes a start switch and a stop switch. Both said switches have respectively two sets of connection points, which, through a reference voltage, pass the voltage signal to a control circuit. Controlling such a control circuit will get much safer on/off protection.

### BRIEF DESCRIPTION OF DRAWINGS

FIG. 1 is a cross-sectional view of a known assembled a-connection switch;

FIG. 2 is a cross-sectional view of a known assembled b-connection switch;

FIG. 3 is a front view of a high voltage tester's panel in a preferred embodiment of the present invention;

FIG. 4 is a cross-sectional view of the preferred embodiment of the present invention, illustrating the connection switch at an initial status in the start or stop circuit;

FIG. 5 is a cross-sectional view of the preferred embodiment of the present invention, illustrating the connection switch after being pressed for operation in the start or stop circuit;

FIG. 6 is a diagram of the preferred embodiment of the present invention, showing the before/after status of the connection switch in the start circuit.

FIG. 7 is a diagram of the preferred embodiment of the present invention, showing the before/after status of the connection switch in the stop circuit.

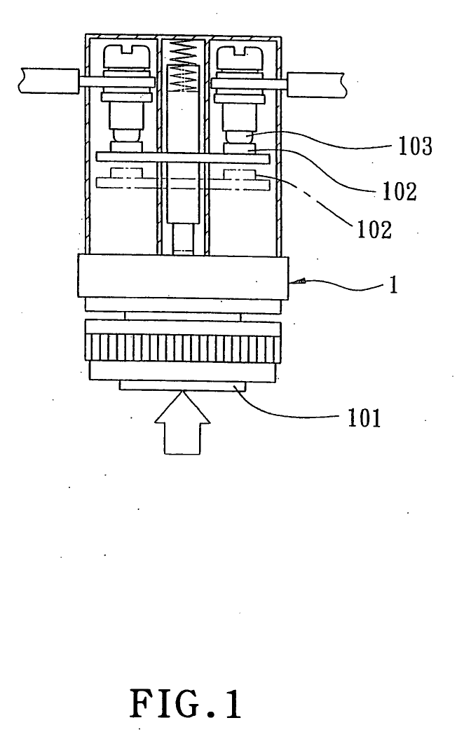

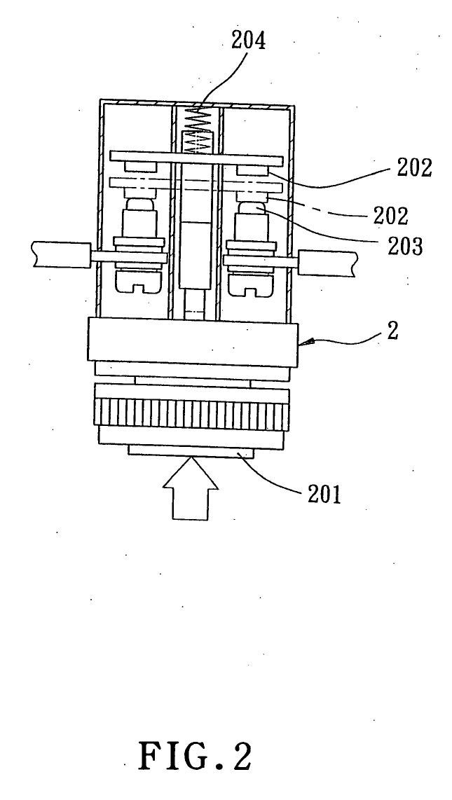

### DETAILED DESCRIPTION OF THE PREFERRED EMBODIMENT

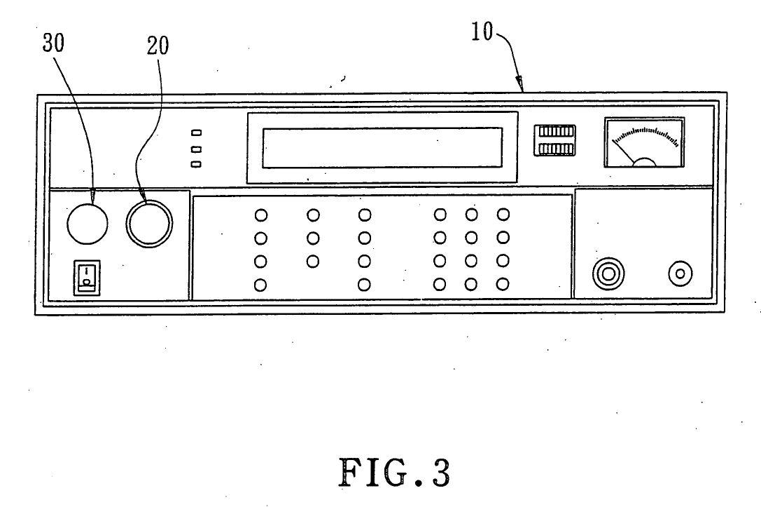

A preferred embodiment of a safety-protective changeover switch of a high voltage tester 10 in the present invention, as shown in FIG. 3, includes a start switch 20 initiating the output of high voltage and a stop switch 30 stopping the voltage output.

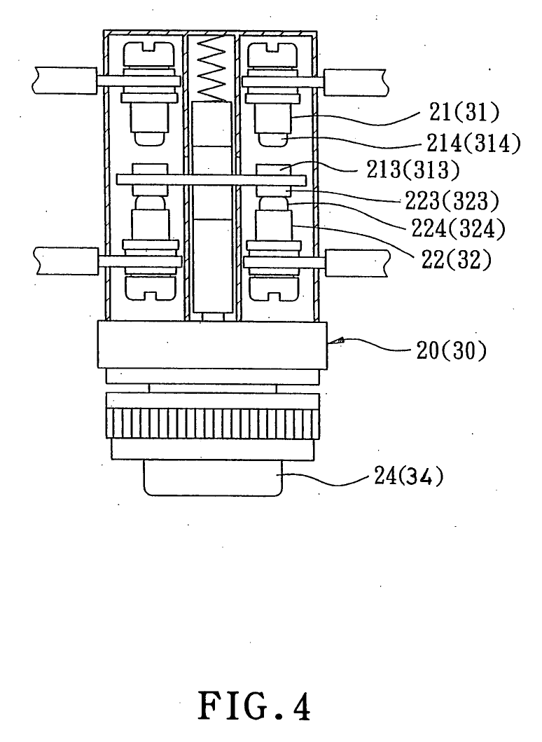

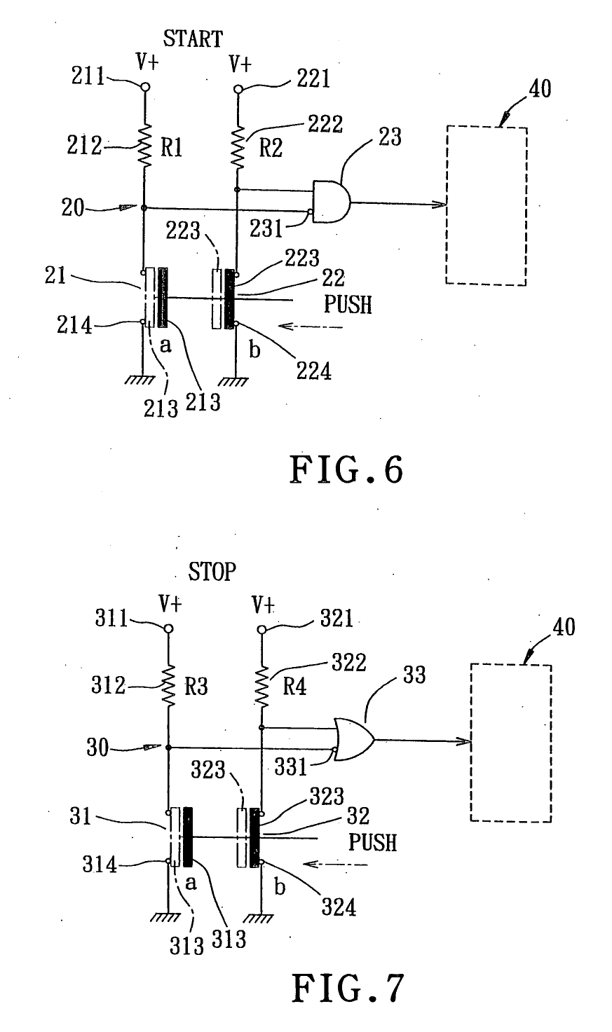

As shown in FIGS. 4 and 6, the start button 20 comprises two sets of connection points that are respectively an a-connection point 21 and a b-connection point 22. The a-, b-connection points 21 and 22, via linking to reference voltages 211 and 221 and shunt resistors 212 and 222 respectively, will transfer in correspondence the voltage signal to the control circuit which is an And Gate 23 having an input pin connected to the circuit of the b-connection point 22 and the other one connecting with a Or Gate 231 first, then to the circuit of the a-connection point 21. Then the And Gate 2 controls the output of high voltage.

As shown in FIGS. 4 and 7, said stop button 30 is composed of two sets of connection points that are respectively a a-connection point 31 and a b-connection point 32. The a-, b-connection points 31 and 32, via linking to reference voltages 311 and 321 and shunt resistors 312 and 322 respectively, will transfer in correspondence the voltage signal to a control circuit which is an Or Gate 33 having an input pin connected to the circuit of the b-connection point 32 and the other input pin connected with an And Gate 331 first and then to the circuit of said a-connection point 31. Then the Or Gate 33 controls to cut off the high voltage.

Following is the operation of the present invention. As shown in FIGS. 4, 6, and 7, said a-connection points 21 and 31 stand in open circuit status and b-connection points 22 and 32 stand in the close circuit status at an initial condition.

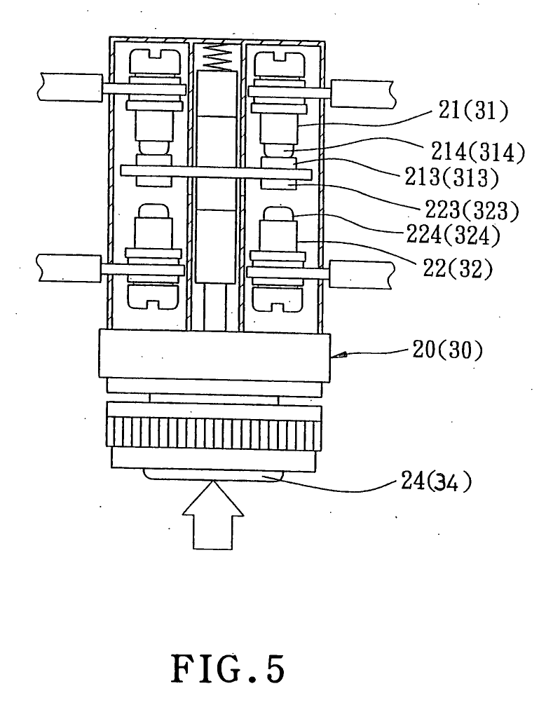

As shown in FIG. 5, when the button 24 of the start switch 20 is pressed down, the movable connecting point 213 of the a-connection point 21 is pushed to contact with the fixed connecting point 214 to become a close circuit and the movable connecting point 223 of the b-connection point 22 disconnects from the fixed connecting point 224 to become a open circuit. Thus far, as shown in FIG. 6, the diagram of the start circuit shows that the signal of the status alternations of a-, b-connection points 21 and 22 goes through said reference voltages 211, 221 and the shunt resistors 212, 222 to the And Gate 23 which, with its two input pins being in high voltage signal, is to pass such high voltage signal to the high voltage circuit 40 to ensure the output of high voltage.

Also, as shown in FIG. 5, when the high voltage is to be shut down, just press down the button 34 of the stop switch 30. Wherein the movable connecting point 313 of the a-connection point 31 is pushed to contact with the fixed connecting point 314 to become a close circuit and the movable connecting point 323 of the b-connection point 32 disconnects from the fixed connecting point 324 to become an open circuit. Thus far, as shown in FIG. 7, the diagram of the stop circuit shows that the signal of the status alternations of a-, b-connection points 31 and 32 goes through the reference voltages 311, 321 and the shunt resistors 312, 322 to the Or Gate 33 which, with any of its input pins being in high voltage signal, is to pass such high voltage signal to the high voltage circuit 40 to cut off the output of high voltage.

Therefore, through the digital control of said And Gate 23 and said Or Gate 33, the output of high voltage can be controlled and cut off steadily and precisely.

Logical gates, that are the And Gate 23 and the Or Gate 33, are used in the preferred embodiment of the invention to obtain the purpose of precise control for start/stop high voltage. Of course, to use diodes array instead or to build in a CPU directly are possible to get a steady control as the gates do. No more drawings and description will be made.

Conclusively, the start switch 20 and the stop switch 30 in the high voltage tester 10 of the present invention are connected to the And Gate 23 and the Or Gate 33 respectively, the a-, b-connection points 21, 22, 31 and 32, being controlled digitally via a logical circuit, alter statuses to enable the And Gate 23 and the Or Gate 33 to pass or cut off the high voltage output precisely. Therefore, the passage or the cutting-off of the high voltage can be steadily and precisely controlled. When one of the a-, b-connection point 21 and 22 in the start switch 20 is out of work, no output of high voltage occurs. On the contrary, even one of the a-, b-connection point 31 and 32 in the start switch 30 is out of work, the other one can still work to cut off high voltage output. So, a safety-protective changeover switch of high voltage tester in the invention not only controls precisely but also provides a user with a safety protection.

While the preferred embodiment of the invention has been described above, it will be recognized and understood that various modifications may be made therein and the appended claims are intended to cover all such modifications that may fall within the spirit and scope of the invention.

What is claimed is:

1. A safety-protective changeover switch of a high voltage tester comprising a start switch and a stop switch for controlling to pass or cut off output of high voltage, characterized by:
said start switch having two sets of connection point, which, through a reference voltage, pass the voltage signal to a control circuit, said control circuit giving a signal to permit high voltage to pass only when both said connection points have altered their statuses; and,
said stop switch having two sets of connection points, which, through a reference voltage, pass a voltage signal to a control circuit, said control circuit giving a signal to cut off the output of high voltage as long as any of said connection points has altered its status.

2. The safety-protecting changeover switch of a high voltage tester as claimed in claim 1, wherein two sets of said connection points in said start switch are respectively composed of an a-connection point and a b-connection point, and two sets of said connection points in said stop switch are also respectively composed of an a-connection point and a b-connection point.

3. The safety-protective changeover switch of high voltage tester as claimed in claim 1, wherein said control circuit of said start switch is mainly an And Gate.

4. The safety-protective changeover switch of a high voltage tester as claimed in claim 1, wherein said control circuit of said stop switch is mainly an Or Gate.
